(19) United States
(12) Patent Application Publication
(10) Pub. No.: US 2023/0125882 A1
(43) Pub. Date: Apr. 27, 2023

(54) SIGNAL TRANSMISSION STRUCTURE

(71) Applicant: QuantumZ Inc., Kaohsiung City (TW)

(72) Inventors: Chun-Chieh CHEN, Kaohsiung City (TW); Ming-Che HSIEH, Kaohsiung City (TW); Po-Ting CHEN, Kaohsiung City (TW)

(21) Appl. No.: 17/506,675

(22) Filed: Oct. 21, 2021

(51) Int. Cl. G02B 6/43; H05K 1/02; H05K 1/18; G02B 6/42

(52) U.S. Cl. CPC G02B 6/43; H05K 1/0274; H05K 1/189; G02B 6/428; G02B 2006/12121

(57) ABSTRACT

A signal transmission structure configured to transmit signals between an image module and an application processor is provided. An optoelectronic composite board including a circuit board and an optical waveguide module, and is configured to simultaneously transmit digital signals between the image module and the application processor in the form of electric and optical signals. By using the signal transmission structure having both electric and optical signals, transferring of a larger quantity of signals is enabled and transmission of digital data is accelerated.

### BACKGROUND

### Technical Field

The present invention relates to a signal transmission structure, and in particular, aims to improve a signal transmission structure of a signal transmission module, to enable the signal transmission structure to rapidly transmit a larger quantity of signals.

### Related Art

Existing digital image pickup systems are applied to, for example, digital image captures, a smart phones, tablet computers, notebook computers, personal computers including a webcam, aerial image systems, driving loggers, WiFi image systems, and doorbell image systems, in which an image is captured using through a digital image pickup systems or sometimes the image is displayed instantly on the screen at the same time. Referring to FIG. 1, the imaging principle of the digital image pickup system is as follows: object-side light enters an image module 10, passes through a lens module 11 of the image module 10, and reaches an image sensor 13 through a filter 12, and photons incident on the image sensor 13 generates movable electric charges. This is called an internal photoelectric effect. The movable electric charges converge to form electric signals, which are then converted into digital signals through internal conversion. The digital signals are transmitted through a circuit board 20 to a processor 30. The processor 30 processes the digital signals, and outputs image data to the screen to form an image of the object or stores the image data.

The circuit board 20 is mainly used for transmitting the digital image data transmitted by the image sensor 13 to the processor 30 for processing, to instantly display the image on the screen or store the image.

In addition, with the development of semiconductor technologies, the quantity of pixels in the image sensor 13 is increased, so images with better image quality can be output. Accordingly, the quantity of digital image data outputted by the image sensor 13 is also greatly increased. The digital image data transmitted by the image sensor 13 cannot all be rapidly transmitted to the application processor 30 by using the digital signal transmission mode of existing circuit boards 20. As a result, when the quantity of digital image data is too large, the signals cannot be instantly transmitted to the screen, leading to a delay in displaying images on the screen. In other words, images captured by the image module 10 cannot be instantly displayed on the screen.

To handle the transmission of a large quantity of signals, a denser circuit design is usually adopted for the existing circuit board 20. However, in the dense circuit layout, electromagnetic wave interference easily occurs between electronic components, and especially when a large quantity of current needs to be transmitted, signal transmission is also interfered, resulting in signal noise and delay.

### SUMMARY

An objective of the present invention is to provide a signal transmission structure, being an optoelectronic composite board, capable of transmitting both electric and optical signals. The signal transmission structure can be applied to a digital image pickup system, and can transmit a larger quantity of signals rapidly.

Another objective of the present invention is to provide a signal transmission structure, being an optoelectronic composite board, capable of transmitting both electric and optical signals, to resolve the problem that an existing circuit board needs a multilayer board design in order to increase the data transmission capacity, thereby reducing the thickness of the signal transmission structure.

Still another objective of the present invention is to provide a signal transmission structure, being an optoelectronic composite board, capable of transmitting both electric and optical signals. Due to the advantages of larger signal transmission and quick transmission, a thermal effect generated by long-time transmission of a large amount of data can be resolved, and an overall life time of an optoelectronic composite board can be improved.

Yet another objective of the present invention is to provide a signal transmission structure, being an optoelectronic composite board, capable of transmitting both electric signals and optical signals, to resolve the problem of excessively dense layout of existing transmission circuit boards, and improve the signal stability.

To resolve the problems, the present invention discloses a signal transmission structure, applied to a digital image pickup system, configured to transmit signals between an image module and an application processor, comprising: an optoelectronic composite board, including a circuit board and an optical waveguide module, configured to convert all or part of digital signals from said image module into optical signals, and to simultaneously transmit signals between said image module and said application processor in the form of electric and optical signals.

The present invention discloses a signal transmission module, comprising: an image module, at least comprising a lens group configured to allow entrance of object-side light, a filter configured to separate and filter the light, and an image sensor configured to convert the light passing through the filter into digital signals of the image data; and an optoelectronic composite board, said optoelectronic composite board including a circuit board and an optical waveguide module, and configured to simultaneously transmit all or part of digital signals from said image module into optical signals, and further to simultaneously output digital signals in the form of electric and optical signals.

The advantages of the present invention lie in that the optoelectronic composite board can transmit digital signals (electric signals) through the circuit board, and can simultaneously transmit optical signals through the optical waveguide module. By using the optical waveguide module, which is capable of rapidly transmitting a larger quantity of signals, a larger quantity of digital data transmitted by the image module can all be rapidly transmitted to the application processor for processing, so that images captured by the image module can be quickly displayed on the screen. The optoelectronic composite board of the invention has the effect of transmitting a larger quantity of signals, can resolve the problem that an existing circuit board needs a multilayer board design in order to increase the data transmission capacity, thereby reducing the thickness of the finished product, and can also resolve the thermal effect caused by long-time signal transmission, thereby prolonging the life time of the product. In addition, the use of the optical waveguide module resolves the problem of electromagnetic wave interference in the case of dense layout of the circuit board, thus improving the signal stability especially in a case where a large current needs to be transferred.

### BRIEF DESCRIPTION OF THE DRAWINGS

FIG. 1 is a schematic diagram of a signal transmission module in the related art.

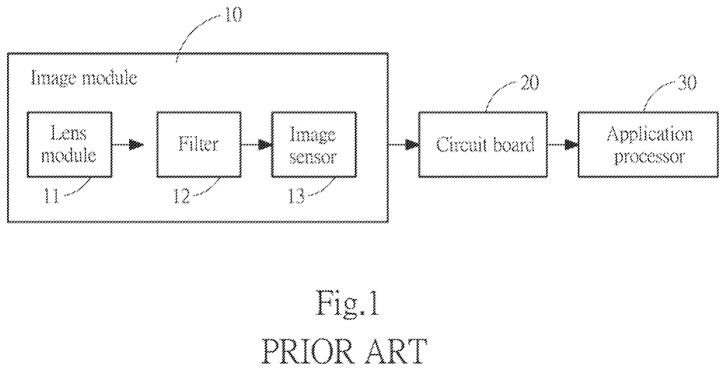

FIG. 2 is a first schematic diagram of a signal transmission module according to the present invention.

FIG. 3 is a second schematic diagram of a signal transmission module according to the present invention.

FIG. 4 is a first implementation schematic diagram of a signal transmission module according to the present invention.

FIG. 5 is a second implementation schematic diagram of a signal transmission module according to the present invention.

### DETAILED DESCRIPTION

To make a person skilled in the art better understand the solutions of the present invention, the technical solutions in the embodiments of the present invention will be clearly and thoroughly described below with reference to the accompanying drawings in the embodiments of the present invention. Apparently, the described embodiments are merely some rather than all of the embodiments of the present invention. Based on the embodiments of the present invention, all other embodiments obtained by making equivalent changes or modifications by a person of ordinary skill in the art shall fall within the scope of the present invention.

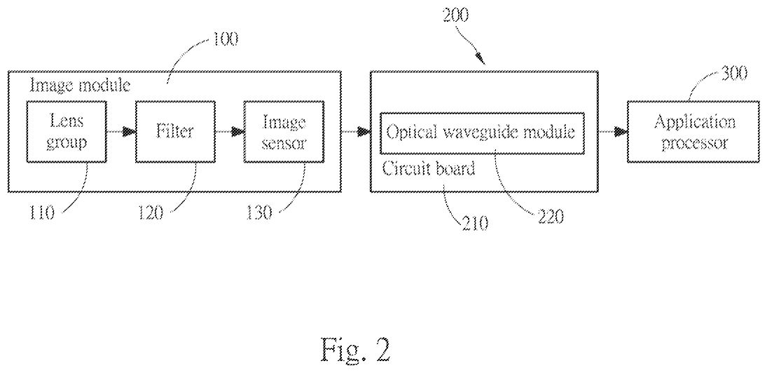

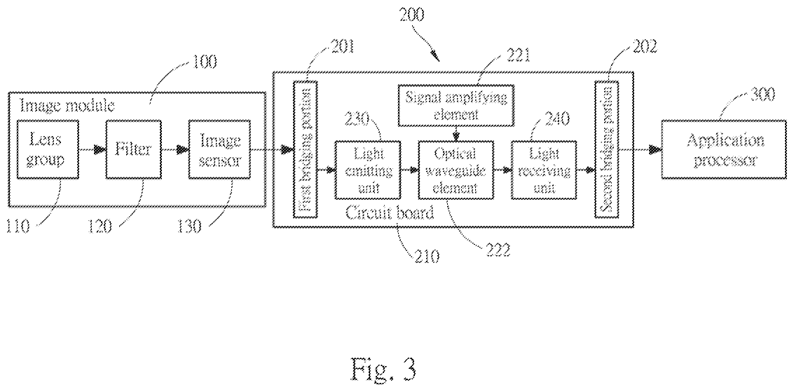

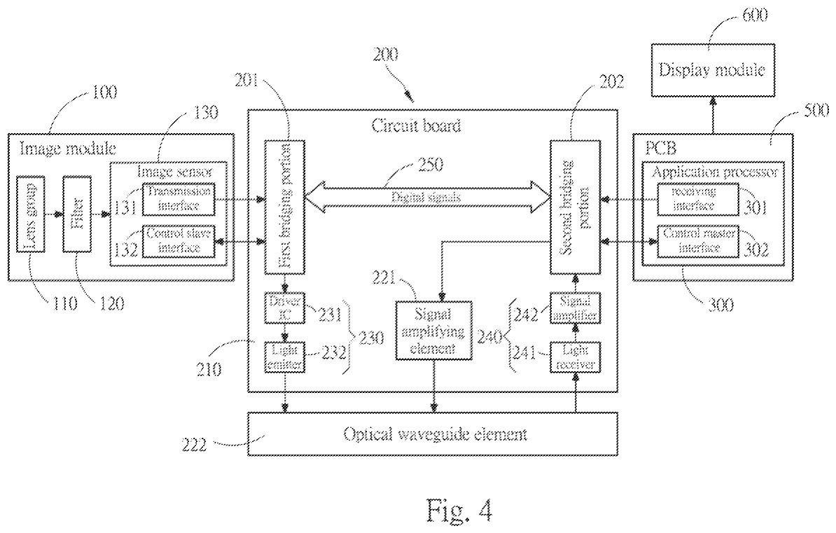

FIG. 2, FIG. 3, and FIG. 4 are schematic diagrams of a signal transmission module and a signal transmission structure according to the present invention. The present invention is applied to a digital image pickup system. The signal transmission module includes an image module 100 and an optoelectronic composite board 200 configured to transmit signals between the image module 100 and an application processor 300.

The image module 100 at least includes a lens group 110, a filter 120, and an image sensor 130. An image capturing action of the image module 100 is: after object-side light enters the image module 100, the lens group 110 allows the object-side light to enter, the filter 120 separates and filters the object-side light, the separated light reaches the image sensor 130, photons strike the image sensor 130 to generate movable charges, through an photoelectric effect in the image sensor 130, the moving charges are converged to form the electric signals, and the electric signals are converted into the digital signals of the image through the internal conversion. All or part of the digital signals are transmitted to the application processor 300 through the optoelectronic composite board 200. The application processor 300 processes the digital signal, and then outputs image data to a display module 600 for displaying images or storing the image data in a storage element (not shown in the figure).

The optoelectronic composite board 200 includes a circuit board 210 and an optical waveguide module 220, and is configured to transmit the signals between the image module and the application processor 300 in the form of electric and optical signals.

In an actual application, the circuit board 210 may be one of a printed circuit board (PCB), a flexible printed circuit board (FPCB), or a rigid-flex board. In practice, the circuit board 210 includes: a first bridging portion 201 configured to electrically connect to the image module and the image sensor 130 in the image module, and a second bridging portion 202 configured to electrically connect to the application processor 300, and configured to transmit digital signals of the image module 100 and the image sensor 130 to the application processor 300. In practice, the circuit board 210 includes a plurality of electronic components, so that the circuit board 210 transmits the digital signals 250 to the application processor 300 in the form of electric signal transmission. In practice, the digital signals 250 herein refer to control signals between the image module 100 and the application processor 300.

In an actual application, the application processor 300 is disposed on a printed circuit board (PCB) 500. The printed circuit board 500 may be a control board of an electronic product such as a digital image capture, a smart phone, a tablet computer, a notebook computer, or a personal computer. In an actual application, the printed circuit board 500 may be externally connected to a memory card and a battery. The image data processed by the application processor 300 is transmitted to a display module 600 by using the printed circuit board 500, and the images are displayed by using the display module 600.

Further, a connection between the first bridging portion 201 and the image sensor 130 and a connection interface between the second bridging 202 and the application processor 300 need to conform to a communication protocol, such as the Mobile Industry Processor Interface (MIPI) communication protocol. Therefore, an interface of an electrical connection between the image sensor 130 and the optoelectronic composite board 200 is standardized, and an interface of an electrical connection between the application processor 300 and the optoelectronic composite board 200 is standardized. In this way, through the standardized interface between the first bridging portion 201 and the second bridging portion 202, the optoelectronic composite board 200 may be applied to and implemented in the image modules 100 manufactured by different manufacturers and the application processors 300 manufactured by different manufacturers.

In an actual application, under a framework of the MIPI communication protocol, the image sensor 130 includes a transmission interface 131 and a control slave interface 132 applied to an image data transmission interface between the first bridge portions 201 and a control interface. The transmission interface 131 may be a D-PHY interface or a C-PHY interface. The control slave interface 132 may be a CCI slave interface of a CCI.

The application processor 300 includes a receiving interface 301 and a control master interface 302 applied to an image data transmission interface between the second bridging portions 202 and a control interface. The receiving interface 301 may be a D-PHY interface or a C-PHY interface, and the control master interface 302 may be a CCI master interface of a CCI.

In an actual application, the optical waveguide module 220 is between the first bridging portion 201 and the second bridging portion 202, and may be configured to transmit all or part of the digital signals of the image sensor 130 to the application processor 300. By using the capacity of quick transmission of the optical signals and transmission of a large amount of data, for current digital image data with higher pixels and higher image quality, a transmission time of the digital signals and the image data transmitted from the image module 100 and the image sensor 130 to the application processor 300 can be greatly reduced.

The optical waveguide module 220 includes a light emitting unit 230, an optical waveguide element 222, and a light receiving unit 240. After upon receiving the digital signals from the image module 100 and the image sensor 130, the light emitting unit 230 converts the digital signals into the optical signals to the optical waveguide element 222, and the optical waveguide element 222 transmits the optical signals.

The optical waveguide element 222 may be one of a slab waveguide, a stripe waveguide, or a fiber waveguide according to a geometric shape. In the product processing process, an appearance of a straight, curved, or grating channel is manufactured. The known optical waveguide element 222 is made of materials such as polymer, epoxy, glass, acryl, and silicon, and a transmission mode of the optical signals in a waveguide may be classified into a single mode (applicable to a wavelength near 1310 nm) and a multi mode (applicable to a wavelength near 850 nm).

In an actual application, the light emitting unit 230 includes a driver IC 231 and a light emitter 232. After receiving the image data and the digital signals of the image sensor 130 and the image module 100, the driver IC 231 drives the light emitter 232. The light emitter 232 converts the image data and the digital signals into optical signals, and emits the optical signals to the optical waveguide element 222.

In practice, the light emitter 232 may be selected from one of an edge emitting laser (EEL), a surface emitting laser (SEL), a vertical-cavity surface-emitting laser (VCSEL), or a light emitting diode (LED).

In practice, a light receiving unit 240 is disposed between the second bridging portion 202 and the optical waveguide element 222. The light receiving unit 240 receives the optical signals transmitted by the optical waveguide element 222, converts the optical signals into digital signals and transmits the digital signals to the application processor 300.

In an actual application, the light receiving unit 240 includes a light receiver 241 and a signal amplifier 242. The light receiver 241 receives the optical signals transmitted by the optical waveguide element 222 and converts the optical signals into digital signals, and then the digital signals are amplified by the signal amplifier 242 and transmitted to the application processor 300 for data processing.

In an actual application, the circuit board 210 includes: a signal amplifying element 221, configured to relay and reamplify the optical signals of the optical waveguide element 222, so that the transmission of the optical signals in the optical waveguide element 222 is performed normally without affecting the reception of signals by the light receiver 241. In practice, the signal amplifying element 221 may be selected from one of an erbium-doped fiber amplifier (EDFA) or a raman amplifier. The signal amplifying element 221 may be operated in an active enhancement and inactive enhancement manners. In the inactive enhancement manner, the application processor 300 may control the operation of the signal amplifying element 221 to relay and reamplify the optical signals of the optical waveguide element 222.

In an actual application, the image module 100 and the optoelectronic composite board 200 may be combined into a product in production. The image sensor 130 is electrically connected to the first bridging portion 201 and is packaged on one surface of the circuit board 210, and the optoelectronic composite board 200 is regarded as an outward-extending transmission structure of the digital image pickup system.

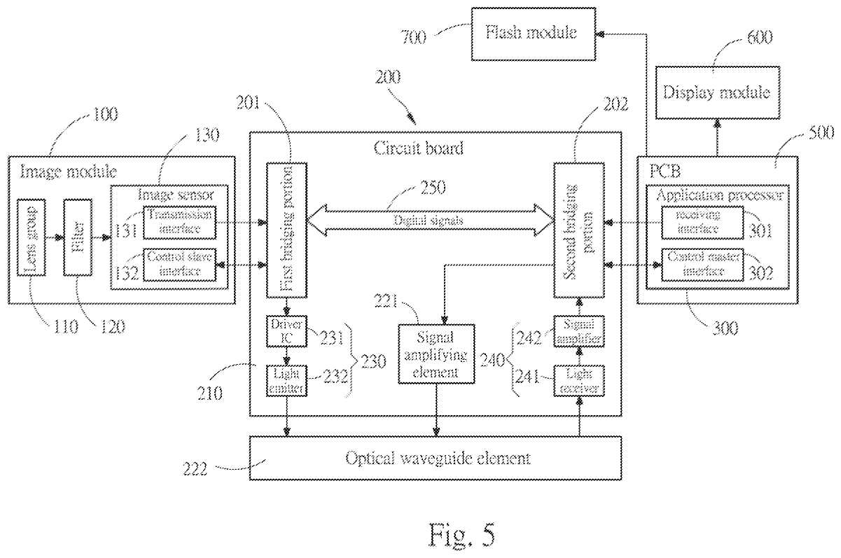

Referring to FIG. 5 again, generally in a digital image pickup system, a printed circuit board (PCB) 500 is used as the control board. The PCB 500 controls a flash module 700, which is configured to detect light and flash during image capturing. In order to flash light, a high current and power are required to drive the flash module 700. Simultaneously, a quantity of signals is transmitting back from the image sensor 130 and driving the flash module 700. Therefore, an electromagnetic effect of high flashing power and a quantity of data transmitting is existed. The present invention resolves the problem of electromagnetic wave interference in the case of dense layout of the conventional transmission circuit board, thus improving the signal stability especially in a case where the large current needs to be transferred.

The advantages of the present invention lie in that the circuit board 210 of the optoelectronic composite board 200 can be configured to transmit the digital signals (electric signals), and the optical waveguide module 220 is configured to transmit the optical signals. By using the optical waveguide module 220, which is capable of rapidly transmitting a large quantity of signals, to transmit the image data outputted by the image sensor 130 in the forms of optical signals, the large quantity of digital image data transmitted by the image sensor 130 can all be rapidly transmitted to the application processor 300 for processing, so that images can be rapidly displayed on the screen 600.

The advantages of the present invention lie in: a concurrent transmission manner in that the optoelectronic composite board used for signal transmission is configured to transmit electric signals through the circuit board, and the optical waveguide module is configured to transmit the optical signals. By utilizing the optical waveguide module, which is capable of rapidly transmitting a large quantity of signals the signal transmission capacity, the requirement of the circuit board for a multilayer board design can be avoided, thereby reducing the thickness of the finished product.

With the capability of rapidly transmitting a larger quantity of signals in the optoelectronic composite board of the invention, the thermal effect caused by long-time signal transmission of the existing circuit board is resolved, thereby prolonging the life time of the product. In addition, the use of the optical waveguide module resolves the problem of electromagnetic wave interference in the case of dense layout of the transmission circuit board, thus improving the signal stability especially in a case where a large current needs to be transferred, for example, when a flash light is turned on.

The above descriptions are merely preferred embodiments of the present invention, and are not intended to limit the scope of the embodiments of the present invention, any simple equivalent replacement and modification according to the scope of the patent application of the present invention and descriptions of the invention shall fall within the protection scope of the present invention.

What is claimed is:

1. A signal transmission structure, configured to transmit signals between an image module and an application processor, comprising:
an optoelectronic composite board, including a circuit board and an optical waveguide module, configured to convert all or part of digital signals from said image module into optical signals, and to simultaneously transmit signals between said image module and said application processor in the form of electric and optical signals.

2. The signal transmission structure of claim 1, wherein said circuit board is one of a printed circuit board (PCB), a flexible printed circuit board (FPCB), or a rigid-flex board.

3. The signal transmission structure of claim 1, wherein said circuit board comprises a first bridging portion connected to said image module and a second bridging portion connected to said application processor, and said optical waveguide module is between said first bridging portion and said second bridging portion.

4. The signal transmission structure of claim 1, wherein said optical waveguide module comprises a light emitting unit, an optical waveguide element, and a light receiving unit;
wherein upon receiving the digital signals from said image module, said light emitting unit converts the signals into optical signals and transmits the optical signals to said light receiving unit through said optical waveguide element;
wherein said light receiving unit converts the optical signals into digital signals and transmits the digital signals to the application processor.

5. The signal transmission structure of claim 4, wherein said circuit board comprises: a signal amplifying element, configured to relay and reamplify the optical signals of the optical waveguide element.

6. The signal transmission structure of claim 4, wherein said signal amplifying element is one of an erbium-doped fiber amplifier (EDFA) or a raman amplifier.

7. The signal transmission structure of claim 4, wherein said optical waveguide element is one of a slab waveguide, a stripe waveguide, or a fiber waveguide, and an appearance of a channel is one of a straight, curved, or grating.

8. The signal transmission structure of claim 4, wherein said light emitting unit comprises a driver IC and a light emitter; wherein after receiving the digital signals of said image module, said driver IC drives said light emitter to emit optical signals to the optical waveguide element.

9. The signal transmission structure of claim 8, wherein said light emitter is one of an edge emitting laser (EEL), a surface emitting laser (SEL), a vertical-cavity surface-emitting laser (VCSEL), and a light emitting diode (LED).

10. The signal transmission structure of claim 4, wherein said light receiving unit comprises a light receiver and a signal amplifier, said light receiver receives the optical signals from said optical waveguide element and converts the optical signals into digital signals, and then the digital signals are amplified by said signal amplifier and transmitted to the application processor.

11. A signal transmission module, comprising:
an image module, at least comprising:
a lens group configured to allow entrance of object-side light, a filter configured to separate and filter the light, and
an image sensor configured to convert the light passing through the filter into digital signals of the image data; and
an optoelectronic composite board, said optoelectronic composite board including a circuit board and an optical waveguide module, configured to convert all or part of digital signals from said image module into optical signals, and further to simultaneously output digital signals in the form of electric and optical signals.

12. The signal transmission module of claim 11, wherein said circuit board is one of a printed circuit board (PCB), a flexible printed circuit board (FPCB), or a rigid-flex board.

13. The signal transmission module of claim 11, wherein said circuit board comprises a first bridging portion connected to the image module and a second bridging portion configured to output digital signals, and the optical waveguide module is between said first bridging portion and said second bridging portion.

14. The signal transmission module according to claim 11, wherein said optical waveguide module comprises a light emitting unit, an optical waveguide element, and a light receiving unit, wherein upon receiving the digital signals from said image module, said light emitting unit converts the signals into optical signals and transmits the optical signals to said light receiving unit through said optical waveguide element, and converts the optical signals into digital signals for output.

15. The signal transmission module according to claim 14, wherein said circuit board comprises: a signal amplifying element, configured to relay and reamplify the optical signals of the optical waveguide element.

16. The signal transmission module according to claim 14, wherein said signal amplifying element is one of an erbium-doped fiber amplifier (EDFA) or a raman amplifier.

17. The signal transmission module according to claim 14, wherein said optical waveguide element is one of a slab waveguide, a stripe waveguide, or a fiber waveguide, and an appearance of a channel is one of a straight, curved, or grating.

18. The signal transmission module of claim 14, wherein said light emitting unit comprises a driver IC and a light emitter; wherein after receiving the digital signals of said image module, said driver IC drives said light emitter to emit optical signals to the optical waveguide element.

19. The signal transmission module of claim 18, wherein said light emitter is one of an edge emitting laser (EEL), a surface emitting laser (SEL), a vertical-cavity surface-emitting laser (VCSEL), or a light emitting diode (LED).

20. The signal transmission module of claim 14, wherein said light receiving unit comprises a light receiver and a signal amplifier, said light receiver receives the optical signals from said optical waveguide element and converts the optical signals into digital signals, and then the digital signals are amplified by the signal amplifier for output.
